(19) United States
(12) Patent Application Publication
(10) Pub. No.: US 2025/0216796 A1
(43) Pub. Date: Jul. 3, 2025

(54) Facet Mirror, Illumination Optical Unit, Arrangement of a Facet Mirror, Projection Exposure Apparatus and Method for Producing a Nanostructured Component

(71) Applicant: Carl Zeiss SMT GmbH, Oberkochen (DE)

(72) Inventor: Martin ENDRES, Koenigsbronn (DE)

(21) Appl. No.: 19/081,272

(22) Filed: Mar. 17, 2025

Related U.S. Application Data
(63) Continuation of application No. PCT/EP2023/075292, filed on Sep. 14, 2023.

(30) Foreign Application Priority Data
Sep. 21, 2022 (DE) 102022209908.7

(51) Int. Cl. G03F 7/00; G02B 5/09

(52) U.S. Cl. CPC G03F 7/70316; G02B 5/09; G03F 7/70225; G03F 7/70833

(57) ABSTRACT

A microlithographic projection exposure apparatus in which the second facet mirror of the illumination optical unit is in the region of the wafer plane, such as below the wafer plane.

### CROSS-REFERENCE TO RELATED APPLICATIONS

The present application is a continuation of, and claims benefit under 35 USC 120 to, international application No. PCT/EP2023/075292, filed Sep. 14, 2023, which claims benefit under 35 USC 119 of German Application No. 10 2022 209 908.7, filed Sep. 21, 2022. The entire disclosure of each of these applications is incorporated by reference herein.

### FIELD

The disclosure relates to a facet mirror for an illumination optical unit of a projection exposure apparatus. The disclosure also relates to an illumination optical unit of a projection exposure apparatus. The disclosure further relates to an arrangement of a facet mirror in the beam path of an illumination optical unit and in the beam path of an optical system of a projection exposure apparatus. In addition, the disclosure relates to an optical system for a projection exposure apparatus, to a projection exposure apparatus, and to a method for producing a nanostructured component.

### BACKGROUND

The basic structure of a projection exposure apparatus, especially of an illumination optical unit with a fly's eye integrator, is known. For details, reference is made to WO 2009/100 856 A1 by way of example.

WO 2016/078 818 A1 has disclosed an optical design of an illumination optical unit, in which a pupil facet mirror is arranged below the wafer plane of the projection exposure apparatus. In this design, two grazing incidence mirrors are arranged in the beam path between the pupil facet mirror and the object field.

WO 2019/096 654 A1 has disclosed an optical design of an illumination optical unit of a projection exposure apparatus, in which a condenser mirror is arranged below the wafer plane. The condenser mirror serves to image the pupil facets of a pupil facet mirror into the object field. The condenser mirror itself is not of a facet-type design.

DE 10 2014 204 388 A1 has likewise disclosed designs for an illumination optical unit of a projection exposure apparatus. The arrangement of a facet mirror below the wafer plane is not known from this reference, especially not from FIG. 1 of the reference, which shows the projection optical unit purely schematically, and obviously not true to detail.

### SUMMARY

The disclosure provides, for example projection exposure apparatuses, and the optical units thereof, is always a desideratum.

According to an aspect of the disclosure, an illumination optical unit for illuminating an object field in an object plane of a projection exposure apparatus comprises a first facet mirror and a second facet mirror, wherein the distance between the second facet mirror and the object plane is at least 1500 mm, such as at least 1800 mm, for example at least 2100 mm, for example at least 2300 mm.

In this case, the distance is measured, in particular, in the direction perpendicular to the object plane or in the direction of the beam path of the illumination radiation, especially of a chief ray incident on a central object field point. Consequently, this is a measure of the desired vertical installation space of the illumination optical unit in particular.

Specifications regarding the distance may relate for example to a minimum distance between the second facet mirror and the object plane. They may also relate to an average distance between the second facet mirror and the object plane. They may also relate to a distance between a central point on the second facet mirror, for example its reflection surface, for example at the geometric centroid of the reflection surface of the second facet mirror, and the object plane.

The labels “first” and “second” facet mirror may for example relate to the sequence thereof in the beam path of the illumination optical unit, especially proceeding from a radiation source module in the direction of the object field. The radiation source module is not a part of the illumination optical unit. Together with the latter, it forms an illumination system of the projection exposure apparatus.

The facet mirrors may each have a multiplicity of physical or virtual individual facets. A physical individual facet should be understood to mean an individual facet formed by a single, mono-lithic mirror, such as by a mirror with a simply connected reflection surface.

A virtual facet should be understood to mean, in particular, a facet formed by a combination of one or more individual mirrors, such as micromirrors.

The facets, such as the individual mirrors, for example the micromirrors, may be displaceable. This is also referred to as the switchability of the individual mirrors, especially of the facets. They may also be static. Combinations are likewise possible.

The facets, especially the individual mirrors, may each have one or two degrees of freedom of tilt, for example. Further degrees of freedom, such as a linear displaceability of the facets, especially of the individual mirrors, is likewise possible.

Especially in the case of virtual facets, the individual mirrors can be formed such that they enable a substantially gap-free tessellation of a surface. For example, this can be a curved surface. The individual mirrors can be arranged on a curved surface in order to reduce the desired switching angles.

The facets, such as the individual mirrors of same, may each have a flat, which is to say plane, reflection surface or a curved, for example a convex or concave, reflection surface. They may also have different optical powers in different directions.

It was found that an arrangement of the second facet mirror at a large distance from the object plane can lead to a multiplicity of desirable features.

In this respect, the reduction of the switching amplitudes is mentioned by way of example. Moreover, this detail can help enable a reduction of the thermal load on the facet mirror and, for example, on its individual mirrors. Further, this detail can help enable a reduction in the angles of incidence, such as a tighter folding of the beam path. Additionally, the complexity of the coating for the individual mirrors can be reduced, or the reflectivity of the same may be increased.

According to a further aspect, an illumination optical unit can be designed so that no further optical components, such as no further mirrors, are arranged in the beam path between the second facet mirror and the object field. It is also possible to arrange one or more stops or obscuration elements, but no further mirrors, in the beam path between the second facet mirror and the object field. This can be desirable for the overall transmission of the illumination optical unit for example, but not mandatory.

According to an aspect of the disclosure, the first facet mirror is arranged at a first distance d1 from the object plane and the second facet mirror is arranged at a distance d2, wherein the following applies: d2/d1>3, such as d2/d1>4, for example d2/d1>5.

The distance d12 from the first facet mirror to the second facet mirror in the direction perpendicular to the object plane or in the direction of the beam path can be at least 60%, such as at least 70%, for example at least 80% of the distance d2 of the second facet mirror from the object plane. For example, the following may apply: 1≤d2/d12≤1.5, such as d2/d12≤1.2, for example d2/d12≤1.1.

As a result of a large distance between the two facet mirrors, it is possible to reduce the switching range desired, which is to say the desired properties with respect to the displaceability of the mirrors of the first facet mirror.

For example, the first facet mirror is arranged as close as possible to the object field without however obscuring the beam path of the illumination optical unit in the process.

The second facet mirror can be arranged at a relatively large distance from the object plane. For example, it may form the structural part of the illumination optical unit which has the greatest distance from the object plane.

According to a further aspect, the imaging scale for imaging the first facets into the object field may be no more than 2, such as no more than 1.5, for example no more than 1.3, for example no more than 1.25, for example no more than 1.2, for example no more than 1.15, for example no more than 1.1.

According to a further aspect, the first facet mirror, as measured in a direction parallel to the object plane, is arranged at a first distance dip from the object field, wherein the following applies: d2/d1p>3, such as d2/d1p>5, for example d2/d1p>10.

In this case, the distance d1p may specify the minimum distance of th first facet mirror from the object field, for example the spacing of the two adjacent edge regions. It may also be the distance from a centroid of the first facet mirror to a central object field point.

The combination of a small distance of the first facet mirror from the object field in the direction parallel to the object plane and a substantially larger distance of the second facet mirror in the direction perpendicular to the object plane can help make it possible to reduce the folding angles on the facet mirrors.

For example, it is possible to arrange the illumination optical unit in a spatial region whose lateral extent, which is to say its extent parallel to the object plane, is less than its vertical extent, which is to say its extent in the direction perpendicular to the object plane.

According to a further aspect, the illumination optical unit may have precisely the two facet mirrors but no further mirrors. For example, the illumination optical unit may be designed as a 2-mirror system. In this case, the two mirrors are facet mirrors with a multiplicity of individual mirrors for example.

For example, it is possible to form the illumination system of the projection exposure apparatus in such a way that no further mirrors apart from the two facet mirrors are arranged in the beam path between the radiation source module, such as between an intermediate focus of the radiation source module, and the object field.

The distance between the first facet mirror and an intermediate focus, such as an intermediate focus of the radiation source module, may be for example at least 1200 mm, such as at least 1400 mm, for example at least 1500 mm.

This may be the distance in the direction perpendicular to the object plane or the distance along the beam path of the illumination radiation. Yet again, this may be the minimum distance or a mean distance in accordance with the preceding description.

A greater distance of the first facet mirror from the intermediate focus of the radiation source can help lead to a reduction of the thermal load on the first facet mirror.

According to a further aspect, the distance between the first facet mirror and the second facet mirror can be at least 1500 mm, such as at least 1700 mm, for example at least 1900 mm.

This may be the distance in the direction perpendicular to the object plane or the distance along the beam path of the illumination radiation in the illumination optical unit. Here, too, this may be a minimum distance or a mean distance in accordance with the preceding description. For example, this can be the minimum of a distance between the two facet mirrors, as measured along a chief ray of the illumination radiation.

The demands on the switching range, which is to say the displaceability of the individual facets, such as of the individual mirrors, for example of the first facet mirror, can be reduced as a result of a large distance between the two facet mirrors.

The illumination optical unit may have an elliptical, for example non-circular, exit pupil. The latter may have an eccentricity of at least 1.1, such as at least 1.2, for example at least 1.3, for example at least 1.5, for example at least 2.

The arrangement of the totality of the facets on the second facet mirror may have a smallest enveloping elliptical boundary curve with an axis ratio a/b of at least 1.1, such as at least 1.3, for example at least 1.5, for example at least 1.7, for example at least 2, for example at least 2.5. However, this is not mandatory. An embodiment of the second facet mirror deviating herefrom is likewise possible.

According to a further aspect, a facet mirror for an illumination optical unit of a projection exposure apparatus, such as a pupil facet mirror, has a multiplicity n of facets, wherein the number n of facets is at least 5000, wherein the facets have a characteristic length of at least 5 mm and wherein the facets have at least two degrees of freedom of pivoting.

In the case of a polygonal design of the facets, the characteristic length denotes the longest side length of the boundary of the reflection surface of the facets in particular. A diameter of a facet may also be referred to as a characteristic length.

The number of facets can also be at least 6000, such as at least 7000, for example at least 8000. It is usually less than 100,000, such as less than 50,000, for example less than 20,000. For example, it may be less than 10,000.

The facets may be arranged on an elliptical carrier.

They may be arranged on a curved carrier. The carrier may have a surface in the form of a spherical cap or toroidal section.

The pupil facet mirror may also have static pupil facets. The pupil facets may have a hexagonal, round, for example circular, or rectangular, such as square, form. They may have a side length or a diameter of at least 5 mm to 7 mm. They may be arranged on a circular carrier. The number n of pupil facets may range from 1000 to 4000. The carrier may have a plane surface.

The pupil facet mirror may also have virtual pupil facets. These may be formed by a micromirror unit (MMU), which is also referred to as a micromirror array. The micromirrors may have edge lengths ranging from 0.5 mm to 2 mm, such as ranging from 0.8 mm to 1.2 mm. The number of mirrors per MMU can be 12×12, 24×24 or 36×36. In this context, the number of columns need not necessarily correspond to the number of rows. By way of example, 3×3, 4×4, 6×6, 8×8 mirrors can be connected together to form a pupil facet. On account of the flexible switchability, the size of the virtual pupil facets can be adapted to the size of the plasma image. By way of example, 3×3 plasma images may fit on one MMU. In principle, the plasma images on an MMU may also have different sizes.

The pupil facet mirror may have a maximum diameter of at least 800 mm, such as at least 1000 mm. Such a large pupil facet mirror enables the use of relatively large pupil facets while simultaneously reducing the degree of pupil filling.

According to an aspect of the disclosure, the second facet mirror may be arranged in the beam path of the illumination optical unit in such a way that a maximum folding angle of the facets of the second facet mirror is no more than 20°, such as no more than 15°, for example no more than 10°.

In this context, the folding angle refers in particular to twice the value of the angle of incidence.

According to a further aspect, the two facet mirrors may be arranged in the beam path of the illumination optical unit in such a way that a maximum folding angle in the beam path of the illumination optical unit, for example between an intermediate focus of the radiation source module and the object field, is no more than 30°, such as no more than 25°, for example no more than 20°.

According to a further aspect, the second facet mirror may be arranged in the beam path of the illumination optical unit in such a way that its distance d2 from the object plane and/or its distance d12 from the first facet mirror—in each case measured in the direction perpendicular to the object plane or measured in the direction of the beam path, in particular of a chief ray of the illumination radiation-is at least 1500 mm, such as at least 1800 mm, for example at least 2100 mm, for example at least 2300 mm.

For example, the following may apply in this context: 1>d12/d2>0.8.

For example, the following may apply: 1≤d2/d12≤1.5, such as d2/d12≤1.25.

According to a further aspect, the second facet mirror may be arranged in the beam path of the projection exposure apparatus in such a way that all distances of adjacent optical elements in the beam path are smaller than a distance d2 of the second facet mirror from the object plane.

The distance d2 of the second facet mirror from the object plane consequently represents the greatest distance between adjacent optical elements in the beam path of the optical system of the projection exposure apparatus. The second largest distance may be formed by the distance between the two facet mirrors.

The features arising from this are evident from those already described.

According to a further aspect, the second facet mirror may be arranged in the beam path of an optical system of the projection exposure apparatus, in the region next to a wafer stage, such as in the region between a radiation source module and a wafer stage.

The installation space available in situ can be used as a result.

For example, the second facet mirror can be arranged in a region below the wafer plane. In this context, the wafer plane refers to the plane in which the wafer to be structured is arranged during the operation of the projection exposure apparatus.

In an optical system for a projection exposure apparatus, the second facet mirror of the illumination optical unit may be arranged at a second distance from the object plane, the second distance being at least as large as a distance of the image plane from the object plane.

In this case, the distances may each be measured in the direction perpendicular to the object plane.

The distance between the second facet mirror and the object plane may be for example at least 0.8-times, such as at least 0.9-times, for example at least 1.05-times, for example at least 1.1-times, for example at least 1.2-times, for example at least 1.3-times as large as the distance dBO between the image plane and object plane. It may be less than 1.4 dBO.

The projection optical unit can be a projection optical unit with anamorphic imaging. For example, the projection optical unit may have imaging scales in the scanning direction and perpendicular thereto, the imaging scales differing from one another by at least 10%, such as by at least 50%, for example by at least 100%, for example by at least 200%, for example by at least 400% in terms of absolute value. The imaging scales may have the same sign. They may also have different signs.

The projection optical unit may have a mechanically accessible or a mechanically inaccessible entrance pupil.

The projection optical unit can have a circular exit pupil.

A projection exposure apparatus according to the disclosure may comprise an illumination optical unit according to the preceding description and/or an optical system according to the preceding description.

The features are evident from those already described.

The disclosure seeks provide an improved method for producing a micro- or nanostructured component and also a corresponding component, for example by using a projection exposure apparatus according to the preceding description. The features are evident from those of the projection exposure apparatus.

### BRIEF DESCRIPTION OF THE DRAWING

Further details and features of the disclosure will become apparent from the below description of exemplary embodiments with reference to the figure.

FIG. 1 shows schematically the beam path of a projection exposure apparatus in a meridional section.

### DETAILED DESCRIPTION

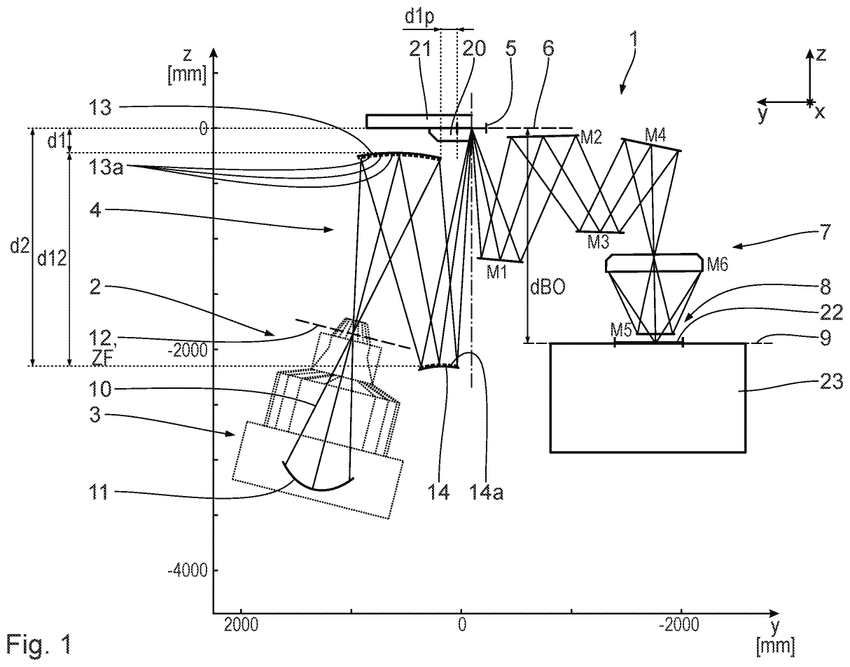

In the following text, certain components of a microlithographic projection exposure apparatus 1 are described first by way of example with reference to FIG. 1. The description of the basic structure of the projection exposure apparatus 1 and its components should not be construed as limiting here. Numerous modifications and alternatives of the general principle are known from the prior art.

An illumination system 2 of the projection exposure apparatus 1, as well as a radiation source 3, has an illumination optical unit 4 for illumination of an object field 5 in an object plane 6. What is exposed here is a reticle 20 arranged in the object field 5. The reticle 20 is held by a reticle holder 21.

The reticle 20 is displaceable in a scanning direction in particular.

A local Cartesian xyz-coordinate system is shown in FIG. 1 for explanation purposes. The reticle 20 serves as a reference point for the coordinate system plotted in FIG. 1. In this case, the scanning direction of the reticle 20 corresponds to the y-direction. The z direction runs perpendicularly to the object plane 6.

The projection exposure apparatus 1 moreover comprises a projection optical unit 7. The projection optical unit 7 serves for imaging the object field 5 into an image field 8 in an image plane 9. A structure on the reticle 20 is imaged onto a light-sensitive layer of a wafer 22 arranged in the region of the image field 8 in the image plane 9. The wafer 22 is held by a wafer holder 23. For example, it is displaceable via the wafer holder 23. It can be displaceable in a manner synchronized with the reticle 20.

The wafer holder 23 is also referred to as a wafer stage.

The radiation source 3 is an EUV radiation source. The radiation source 3 emits EUV radiation 10, which is also referred to below as used radiation or illumination radiation. For example, the used radiation has a wavelength in the range between 5 nm and 30 nm. The radiation source 3 can be a plasma source. It may also be a synchrotron-based radiation source.

The illumination radiation 10 emerging from the radiation source 3 is focused by a collector 11.

The illumination radiation 10 propagates through an intermediate focal plane 12 downstream of the collector 11. The intermediate focal plane 12 may represent a separation between the radiation source module and the illumination optical unit. The radiation source module may comprise the collector 11 in addition to the radiation source 3. It may also comprise further components. For example, the radiation source module may comprise an evacuatable housing.

The illumination optical unit 4 comprises a first facet mirror 13. If the first facet mirror 13 is arranged in a plane of the illumination optical unit 4 which is optically conjugate to the object plane 6, then this facet mirror is also referred to as a field facet mirror 13. The first facet mirror 13 comprises a multiplicity of individual first facets 13a, which are also referred to hereinbelow as field facets.

As known for example from DE 10 2008 009 600 A1, the first facets 13a themselves may be composed in each case of a multiplicity of individual mirrors, for example a multiplicity of micromirrors. The first facet mirror 13 may for example be formed as a microelectromechanical system (MEMS system). For details, reference is made to DE 10 2008 009 600 A1.

In the beam path of the illumination optical unit 4, a second facet mirror 14 is arranged down-stream of the first facet mirror 13. If the second facet mirror 14 is arranged in a pupil plane of the illumination optical unit 4, it is also referred to as a pupil facet mirror.

In this case, the combination of the first facet mirror 13 and the second facet mirror 14 is also referred to as a fly's eye integrator. Such a variant can be desirable provided the entrance pupil plane of the projection optical unit 7 is located upstream of the object field 5 and is freely accessible. The facets 13a of the first facet mirror 13 are for example switchable at full transmission for a flexible pupil illumination. They can be in the form of physical facets or virtual facets, which are formed by grouping micromirrors. They can approximate the original image of the field to be illuminated in the object field 5, for example on the reticle 20. Static or switchable facets 14a may be used on the second facet mirror 14. They can be in the form of physical facets or virtual facets, which is to say by grouping micromirrors.

The second facet mirror 14 may also be arranged at a distance from a pupil plane of the illumination optical unit 4. In this case, the combination of the first facet mirror 13 and the second facet mirror 14 is also referred to as a specular reflector.

This concept can be desirable, especially in the case of an inaccessible entrance pupil plane. The concept of the specular reflector enables light mixing, field forming and flexible pupil illumination using only two reflections at a high transmission.

For a specular reflector, the facets 13a of the first facet mirror 13 can be embodied as virtual facets for example.

For a specular reflector, the second facets 14a of the second facet mirror 14 are designed to be switchable. They may be in the form of physical facets or virtual facets.

The second facet mirror 14a comprises a plurality of second facets 14a. In the case of a pupil facet mirror, the second facets 14a are also referred to as pupil facets.

The second facets 14a may be in the form of virtual facets and may each be composed of a multiplicity of individual mirrors, for example a multiplicity of micromirrors. The second facet mirror 14 may for example be formed as a microelectromechanical system (MEMS system). For details, reference is made to DE 10 2008 009 600 A1.

The illumination optical unit 4 consequently forms a doubly faceted system. This fundamental principle is also referred to as a fly's eye condenser (fly's eye integrator).

As will still be explained in more detail hereinbelow, it may be desirable to arrange the second facet mirror 14 not exactly in a plane that is optically conjugate to a pupil plane of the projection optical unit 7.

With the aid of the second facet mirror 14, the individual first facets 13a are imaged into the object field 5.

Together, the illumination optical unit 4 and the projection optical unit 7 form an optical system in the projection exposure apparatus 1.

The projection optical unit 7 comprises a plurality of mirrors Mᵢ, which are consecutively numbered in accordance with their arrangement in the beam path of the projection exposure apparatus 1.

In the example illustrated in FIG. 1, the projection optical unit 7 comprises eight mirrors M₁ to M₈. Alternatives with four, six, ten, twelve or any other number of mirrors Mᵢ are likewise possible.

For example, the projection optical unit 7 have an anamorphic design. For example, it has different imaging scales βₓ, β_{y} in the x- and y-directions. The two imaging scales βₓ, β_{y} of the projection optical unit 7 can be at (βₓ, β_{y})=(+0.25, −0.125). The projection optical unit 7 consequently leads to a reduction in size with a ratio of 4:1 in the x-direction, which is to say in a direction perpendicular to the scanning direction.

The projection optical unit 7 leads to a reduction in size of 8:1 in the y-direction, which is to say in the scanning direction.

Other imaging scales are likewise possible. Imaging scales with the same sign are also possible in the x- and y-directions.

By way of an assigned pupil facet 14a, the field facets 13a are imaged in each case onto the reticle 20 for the purposes of illuminating the object field 5.

Following the scan integration, it is desirable for the illumination of the object field to be as homogeneous as possible. It can have a uniformity error of less than 2%.

The field uniformity may be achieved by way of an overlay of different illumination channels.

The pupil uniformity may be achieved by way of a redistribution of the illumination channels.

The illumination of the entrance pupil of the projection optical unit 7 can be defined geometrically by way of an arrangement of the pupil facets. The intensity distribution in the entrance pupil of the projection optical unit 7 can be set by selecting the illumination channels, for example the subset of the pupil facets which guide light.

The projection optical unit 7 may have for example a homocentric entrance pupil. The latter may be accessible. It may also be inaccessible.

As illustrated in FIG. 1 by way of example, the second facet mirror 14 may be arranged below the image plane 9, which is also referred to as the wafer plane. This can lead to a desirable use of the available installation space.

A corresponding arrangement of the second facet mirror 14 can lead to a particularly large distance between the second facet mirror 14 and the object field 5.

The first facet mirror 13 may be arranged in the vicinity of the object field 5. As a result, it is possible to obtain a particularly large distance between the first facet mirror 13 and the second facet mirror 14. For example, the distance between the first facet mirror 13 and the second facet mirror 14 may be 2 m or more.

As a result of arranging the first facet mirror 13 in the vicinity of the object field 5, it is also possible to increase the distance of the first facet mirror 13 from an intermediate focus (ZF), located in the intermediate focal plane 12, of the radiation source 3. As a result, it is possible for example to reduce the thermal load on the first facet mirror 13.

It was possible to show that the thermal load on the second facet mirror 14 can be reduced by increasing the distance of the same from the object field 5.

The size of the second facets 14a also increases with increasing distance of the second facet mirror 14 from the reticle 20. This also leads to a reduced thermal load on the second facets 14a.

Further, it was possible to show that the demands on the desired switching angles for the facets 13a, 14a on the first facet mirror 13 and the second facet mirror 14 could be reduced by increasing the distances between these two mirrors.

The demands on the desired switching angles of the facets 13a, 14a on the first facet mirror 13 and the second facet mirror 14 can also be reduced by increasing the distance of the second facet mirror 14 from the object field 5.

Additionally, it was recognized that the desired properties of the switching angle may differ in the scanning direction and perpendicular thereto. The switching amplitudes of the individual mirrors of the first facet mirror 13 and/or second facet mirror 14 may be greater in the direction perpendicular to the scanning direction than in the direction parallel to the scanning direction.

A fly's eye integrator may have smaller switching angles for a homocentric projection optical unit 7 that is to be illuminated divergently.

The switching angle demands for the mirrors of the first facet mirror 13 can also be reduced by the use of a collimated illumination.

What is claimed is:

1. An illumination optical unit configured to guide illumination radiation along a beam path to illuminate an object field in an object plane, the illumination optical unit comprising:
a first facet mirror; and
a second facet mirror,
wherein a distance between the second facet mirror and the object plane is at least 1500 millimeters (mm), and no further mirrors are arranged between the second facet mirror and the object field along the beam path of the illumination radiation.

2. The illumination optical unit of claim 1, wherein:
the second facet mirror is arranged a first distance (d12) from the first facet mirror;
the second facet mirror is a second distance (d2) from the object plane; and
1≤d2/d12≤1.5.

3. The illumination optical unit of claim 1, wherein:
the first facet mirror is a first distance (d1p) from the object field as measured in a direction parallel to an object plane;
the second facet mirror is a second distance (d2) from the object field as measured in a direction perpendicular to the object plane; and
d2/d1p>3.

4. The illumination optical unit of claim 1, wherein the facets of the first facet mirror are imageable into the object field via the facets of the second facet mirror with an imaging scale of at most two.

5. The illumination optical unit of claim 1, wherein the illumination optical unit has exactly two facet mirrors and no further mirrors.

6. The illumination optical unit of claim 1, wherein a distance between the first facet mirror and an intermediate focus of a radiation source for the radiation is at least 1200 mm.

7. The illumination optical unit of claim 1, wherein a distance between the first facet mirror and the second facet mirror is at least 1500 mm.

8. The illumination optical unit of claim 1, wherein, for all adjacent optical elements of the illumination optical unit, a distance between the adjacent optical elements along the beam path of the radiation is less than the distance between the second facet mirror and the object plane.

9. An apparatus, comprising:
an illumination optical unit according to claim 1; and
a projection optical unit configured to image the illuminated object field into an image field in an image plane.

10. A method of operation a microlithographic projection exposure apparatus comprising an illumination optical unit and a projection lens, the projection lens comprising a plurality of mirror devices, the method comprising:
using the illumination optical unit to illuminate an object in an object plane of the projection lens; and
using the plurality of mirror devices to image the illuminated object into an image plane of the projection lens,
wherein the illumination optical unit is an illumination optical unit according to claim 1.

11. A facet mirror, comprising:
at least 5000 facets,
wherein the facets have a characteristic length of at least five millimeters, and the facets have at least two degrees of freedom of pivoting.

12. An illumination optical unit, comprising a facet mirror according to claim 11.

13. An apparatus, comprising:
an illumination optical unit comprising a facet mirror according to claim 11, the illumination optical unit configured to illuminate an object field in an object plane; and
a projection optical unit configured to image the illuminated object field into an image field in an image plane.

14. A method of operation a microlithographic projection exposure apparatus comprising an illumination optical unit and a projection lens, the projection lens comprising a plurality of mirror devices, the method comprising:
using the illumination optical unit to illuminate an object in an object plane of the projection lens; and
using the plurality of mirror devices to image the illuminated object into an image plane of the projection lens,
wherein the illumination optical unit comprises a facet mirror according to claim 11.

15. An apparatus, comprising:
an illumination optical unit configured to illuminate an object field in an object plane; and
a projection optical unit configured to image the illuminated object field into an image plane,
wherein:
the image plane is arranged at a distance (dBO) from the object plane;
the illumination optical unit comprises a first facet mirror and a second facet mirror;
the second facet mirror is arranged at a distance (d2) from the object plane; and
0.8≤d2/dBO<1.4.

16. A method, comprising:
providing the apparatus of claim 15;
using the illumination optical unit to illuminate an object in an object plane of the projection lens; and
using the plurality of mirror devices to image the illuminated object into an image plane of the projection lens.

17. An apparatus, comprising:
a radiation source module comprising a radiation source configured to provide illumination radiation;
an illumination optical unit configured to illuminate an object field in an object plane with the illumination radiation;
a projection optical unit configured to image the object field into an image field of the projection optical unit; and
a wafer stage configured to hold a wafer in the image field,
wherein the illumination optical unit comprises a first facet mirror and a second facet mirror, and the second facet mirror is in a region between the radiation source module and the wafer stage.

18. A method, comprising:
providing the apparatus of claim 17;
using the illumination optical unit to illuminate an object in an object plane of the projection lens; and
using the plurality of mirror devices to image the illuminated object into an image plane of the projection lens.

19. An optical system, comprising:
an illumination optical unit configured to illuminate an object in an object field in an object plane, the illumination optical unit comprising a first facet mirror and a second facet mirror; and
a projection optical unit configured to image the illuminated object into an image plane,
wherein the image plane is arranged a first distance (dBO) from the object plane; the second facet mirror is a second distance from the object plane; and
0.8≤d2/dBO<1.4.

20. A method, comprising:
providing the optical system of claim 19;
using the illumination optical unit to illuminate an object in an object plane of the projection lens; and
using the plurality of mirror devices to image the illuminated object into an image plane of the projection lens.
